(19) United States
(12) Patent Application Publication
(10) Pub. No.: US 2026/0047203 A1
(43) Pub. Date: Feb. 12, 2026

(54) DISPLAY DEVICE INCLUDING REPAIR MEMBERS AND ELECTRONIC APPARATUS INCLUDING THE SAME

(71) Applicant: Samsung Display Co., LTD., Yongin-si (KR)

(72) Inventors: SINUK PARK, Yongin-si (KR); YONGMYEONG KIM, Yongin-si (KR); BYEONGJOO MIN, Yongin-si (KR); SANG-SOO PARK, Yongin-si (KR)

(73) Assignee: Samsung Display Co., LTD., Yongin-si (KR)

(21) Appl. No.: 19/185,903

(22) Filed: Apr. 22, 2025

(30) Foreign Application Priority Data
Aug. 12, 2024 (KR) 10-2024-0107447

(51) Int. Cl. H10D 86/40; H10D 86/60; H10K 59/131

(52) U.S. Cl. CPC H10D 86/443; H10D 86/60; H10K 59/131

(57) ABSTRACT

A display device may include a conductive member disposed on a substrate, at least one wiring member electrically connected to the conductive member, at least one light emitting member disposed on the at least one wiring member, and at least one repair member disposed between the conductive member and the at least one wiring member and preventing a short circuit among the conductive member, the at least one wiring member and the at least one light emitting member.

### CROSS-REFERENCE TO RELATED APPLICATION(S)

This application claims priority to and benefits of Korean Patent Application No. 10-2024-0107447 under 35 U.S.C. § 119, filed on Aug. 12, 2024 in the Korean Intellectual Property Office (KIPO), the content of which is herein incorporated by reference in its entirety.

### BACKGROUND

### 1. Technical Field

Embodiments relate to a display device including a repair member and an electronic apparatus including a display device. More particularly, embodiments relate to a display device including at least one repair member for preventing short circuits among at least one wiring members, a conductive member and at least one light emitting member, and an electronic apparatus including the display device.

### 2. Description of the Related Art

A display device such as an organic light emitting display device or a liquid crystal display device may usually include a plurality of pixels arranged in a pixel region. For example, each of the pixels may include a thin film transistor (TFT), a capacitor and wirings for connecting the pixel to circuits in a peripheral region.

In the processes for manufacturing this display device, failure may occur in the pixels. For example, failure such as a short circuit or an open circuit may occur between the transistors and wirings disposed in the pixel region. Since the numbers of the wirings increases as the integration and resolution of the display device increase, wirings near wirings having failure may be damaged in a repair process in case that the repair process is performed on the wirings having failure using a laser. Further, in case that additional wirings or conductive members are formed on the damaged wirings or the wirings having failure, the underlying damaged wirings or the underlying wirings having failure may not be repaired by the repair process.

### SUMMARY

Embodiments provide a display device including at least one repair member for preventing short circuits among at least one wiring members, a conductive member, and at least one light emitting member.

Embodiments provide an electronic apparatus including a display device having at least one repair member for preventing short circuits among at least one wiring members, a conductive member and at least one light emitting member.

According to embodiments, there is provided a display device including a conductive member disposed on a substrate, at least one wiring member disposed on the conductive member and electrically connected to the conductive member, at least one light emitting member disposed on the at least one wiring member, and at least one repair member disposed between the conductive member and the at least one wiring member and preventing a short circuit among the conductive member, the at least one wiring member and the at least one light emitting member.

In embodiments, the at least one wiring member may include a first wiring member and a second wiring member. The at least one repair member may include a first repair member and a second repair member. The first repair member may be disposed between the conductive member and the first wiring member and prevent a short circuit between the conductive member and the first wiring member. The second repair member may prevent a short circuit between the second wiring member and the at least one light emitting member.

In embodiments, the first wiring member may include at least one scan line and the conductive member may include at least one connection pattern. The first repair member may be disposed between the at least one scan line of the conductive member and the at least one connection pattern of the conductive member and prevent a short circuit between the at least one scan line of the conductive member and the at least one connection pattern of the conductive member.

In embodiments, the first repair member may be disposed on the at least one connection pattern of the conductive member.

In embodiments, the second wiring member may include at least one connection pattern and the second repair member may prevent a short circuit between the at least one connection pattern of the second wiring member and the at least one light emitting member.

In embodiments, the second wiring member may partially overlap the conductive member.

In embodiments, the second repair member may be disposed on the at least one connection pattern of the second wiring member.

In embodiments, each of the first repair member and the second repair member may include an organic insulation material. For example, the organic insulation material may include polyimide, polyamide, acrylic resin, benzocyclobutene resin, phenol resin, or combinations thereof.

In some embodiments, each of the first repair member and the second repair member may include an inorganic insulation material. For example, the inorganic insulation material may include silicon oxide (SiOₓ), silicon nitride (SiNx), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or combinations thereof.

According to embodiments, there is provided a display device including a conductive member disposed on a substrate, a first wiring member and a second wiring member disposed on the conductive member and electrically connected to the conductive member, at least one light emitting member disposed on the first wiring member and the second wiring member, a first repair member disposed between a portion of the first wiring member and a portion of the conductive member and preventing a short circuit between the portion of the first wiring member and the portion of the conductive member, and a second repair member disposed between a portion of the second wiring member and the at least one light emitting member and preventing a short circuit between the portion of the second wiring member and the at least one light emitting member.

In embodiments, the display device may additionally include a plurality of transistors arranged on the substrate. The plurality of transistors may be electrically connected to the conductive member, the first wiring member and the second wiring member, respectively.

In embodiments, the first wiring member may include a scan line and the conductive member may include a connection pattern. The first repair member may be disposed between the scan line of the first wiring member and the connection pattern of the conductive member and prevent a short circuit between the scan line of the first wiring member and the connection pattern of the conductive member.

In embodiments, the second wiring member may include a connection pattern and the second repair member may be disposed between the connection of the second wiring member and the at least one light emitting member and prevent a short circuit between the connection of the second wiring member and the at least one light emitting member.

In embodiments, each of the first repair member and the second repair member may include an organic insulation material.

In some embodiments, each of the first repair member and the second repair member may include an inorganic insulation material.

According to embodiments, there is provided a display device including a plurality of transistors arranged on a substrate, a conductive member electrically connected to the plurality of transistors, a first wiring member and a second wiring member electrically connected to the plurality of transistors and the conductive member, a first light emitting member and a second light emitting member disposed on the first wiring member and the second wiring member, a first repair member disposed between a portion of the first wiring member and a portion of the conductive member and preventing a short circuit between the portion of the first wiring member and the portion of the conductive member, and a second repair member disposed between a portion of the second wiring member and the second light emitting member and preventing a short circuit between the portion of the second wiring member and the second light emitting member.

In embodiments, the first repair member may be disposed on the portion of the first wiring member and the second repair member may be disposed on the portion of the second wiring member.

In embodiments, each of the first repair member and the second repair member may include one selected from an organic insulation material and an inorganic insulation material.

An electronic apparatus according to embodiments may include a processor providing an image data signal and an input control signal, a memory storing an information for operating the processor, and a display device processing the image data signal and the input control signal, and outputting an image information on a display screen. The display device may include a plurality of transistors on a substrate, a conductive member electrically connected to the plurality of transistors, a first wiring member and a second wiring member electrically connected to the plurality of transistors and the conductive member, a first light emitting member and a second light emitting member on the first wiring member and the second wiring member, a first repair member disposed between a portion of the first wiring member and a portion of the conductive member and preventing a short circuit between the portion of the first wiring member and the portion of the conductive member, and a second repair member disposed between a portion of the second wiring member and the second light emitting member and preventing a short circuit between the portion of the second wiring member and the second light emitting member.

The first repair member may be disposed on the portion of the first wiring member, and the second repair member may be disposed on the portion of the second wiring member.

Each of the first repair member and the second repair member may include at least one of an organic insulation material and an inorganic insulation material.

According to embodiments, the first repair member may block the electrical connection between the portion of the conductive member and the portion of the first wiring member in case that the short circuit occurs between the portion of the conductive member and the portion of the first wiring member due to impurities and/or process errors. Additionally, the second repair member may block the electrical connection between the portion of the second wiring member and the second light emitting member in case that the short circuit occurs between the portion of the second wiring member and the second light emitting member due to the impurities and/or the process errors. Therefore, failure such as line defect may be effectively prevented in the display device.

### BRIEF DESCRIPTION OF THE DRAWINGS

Illustrative, non-limiting embodiments will be more clearly understood from the following detailed description in conjunction with the accompanying drawings.

FIG. 1 is a schematic plan view illustrating a display device according to embodiments.

FIGS. 2, 3, 5, and 6 are schematic cross-sectional views illustrating the levels of the layers in the display device according to embodiments.

FIG. 4 is a schematic cross-sectional view illustrating a repair member in the display device according to embodiments.

FIG. 7 is a schematic block diagram illustrating an electronic apparatus according to embodiments.

FIG. 8 illustrates schematic perspective views various electronic apparatuses according to embodiments.

### DETAILED DESCRIPTION OF EMBODIMENTS

In the following description, for the purposes of explanation, numerous specific details are set forth in order to provide a thorough understanding of various embodiments or implementations of the invention. As used herein, “embodiments” and “implementations” are interchangeable words that are non-limiting examples of devices or methods disclosed herein. It is apparent, however, that various embodiments may be practiced without these specific details or with one or more equivalent arrangements. Here, various embodiments do not have to be exclusive nor limit the disclosure. For example, specific shapes, configurations, and characteristics of an embodiment may be used or implemented in another embodiment.

Unless otherwise specified, the illustrated embodiments are to be understood as providing features of the invention. Therefore, unless otherwise specified, the features, components, modules, layers, films, panels, regions, and/or aspects, etc. (hereinafter individually or collectively referred to as “elements”), of the various embodiments may be otherwise combined, separated, interchanged, and/or rearranged without departing from the scope of the invention.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified. Further, in the accompanying drawings, the size and relative sizes of elements may be exaggerated for clarity and/or descriptive purposes. In case that an embodiment may be implemented differently, a specific process order may be performed differently from the described order. For example, two consecutively described processes may be performed substantially at the same time or performed in an order opposite to the described order. Also, like reference numerals denote like elements.

In case that an element or a layer is referred to as being “on,” “connected to,” or “coupled to” another element or layer, it may be directly on, connected to, or coupled to the other element or layer or intervening elements or layers may be present. In case that, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Further, the axis of the first direction DR1, the axis of the second direction DR2, and the axis of the third direction DR3 are not limited to three axes of a rectangular coordinate system, such as the X, Y, and Z-axes, and may be interpreted in a broader sense. For example, the axis of the first direction DR1, the axis of the second direction DR2, and the axis of the third direction DR3 may be perpendicular to one another, or may represent different directions that are not perpendicular to one another. For the purposes of this disclosure, “at least one of A and B” may be understood to mean A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one element's relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature and the shapes of these regions may not reflect actual shapes of regions of a device and, as such, are not necessarily intended to be limiting.

As customary in the field, some embodiments are described and illustrated in the accompanying drawings in terms of functional blocks, units, and/or modules. Those skilled in the art will appreciate that these blocks, units, and/or modules are physically implemented by electronic (or optical) circuits, such as logic circuits, discrete components, microprocessors, hard-wired circuits, memory elements, wiring connections, and the like, which are formed using semiconductor-based fabrication techniques or other manufacturing technologies. In the case of the blocks, units, and/or modules being implemented by microprocessors or other similar hardware, they may be programmed and controlled using software (e.g., microcode) to perform various functions discussed herein and may optionally be driven by firmware and/or software. It is also contemplated that each block, unit, and/or module may be implemented by dedicated hardware, or as a combination of dedicated hardware to perform some functions and a processor (e.g., one or more programmed microprocessors and associated circuitry) to perform other functions. Also, each block, unit, and/or module of some embodiments may be physically separated into two or more interacting and discrete blocks, units, and/or modules without departing from the scope of the invention. Further, the blocks, units, and/or modules of some embodiments may be physically combined into more complex blocks, units, and/or modules without departing from the scope of the invention.

Display devices according to embodiments may be employed (or implemented) in various electronic apparatuses. The electronic apparatuses may include the display devices according to embodiments and may additionally or selectively include modules or devices having optional functions.

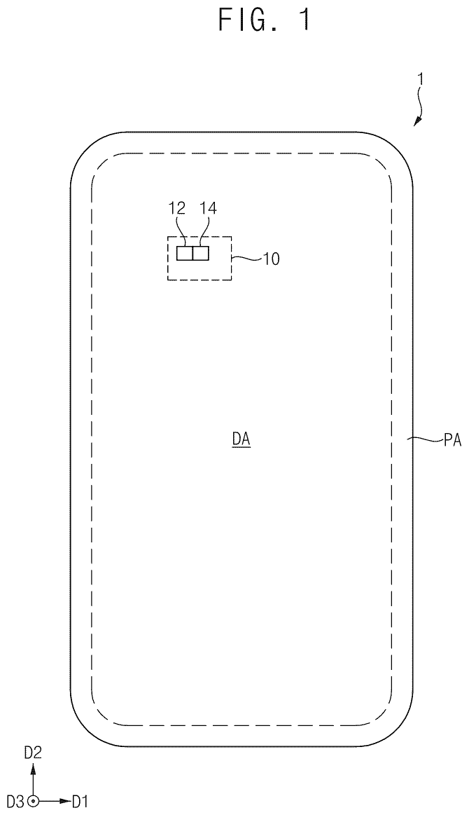

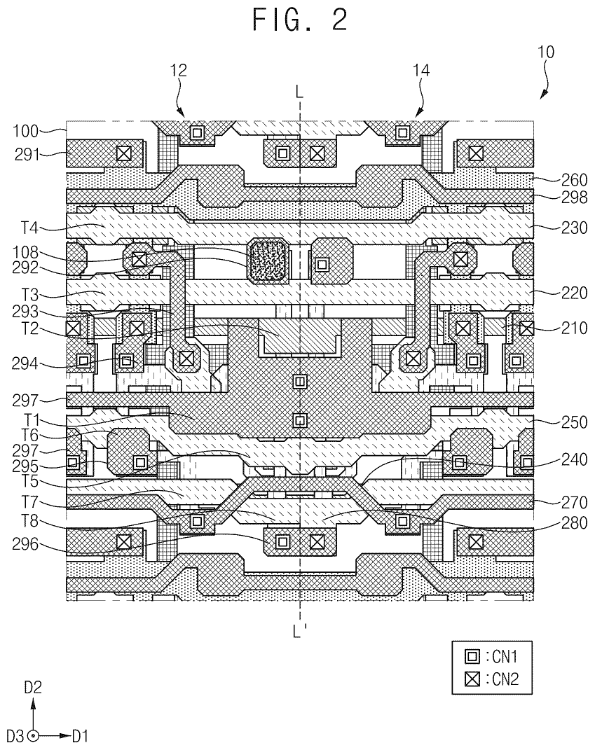

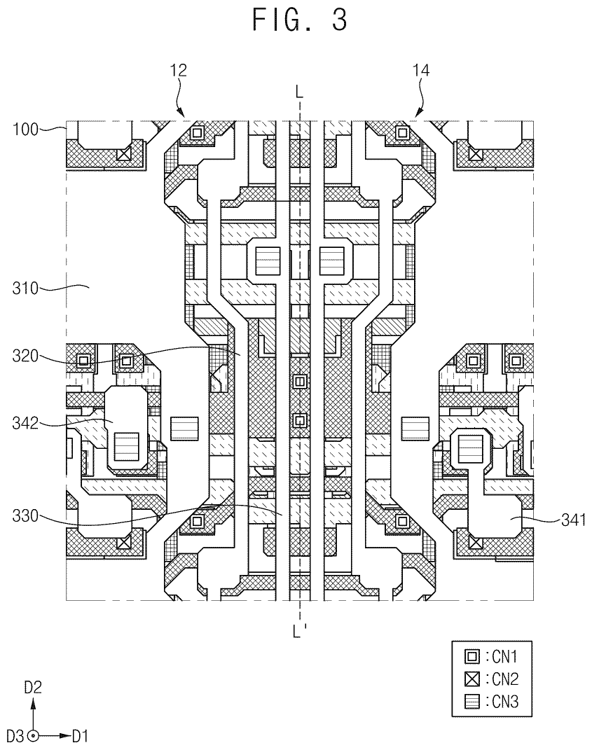

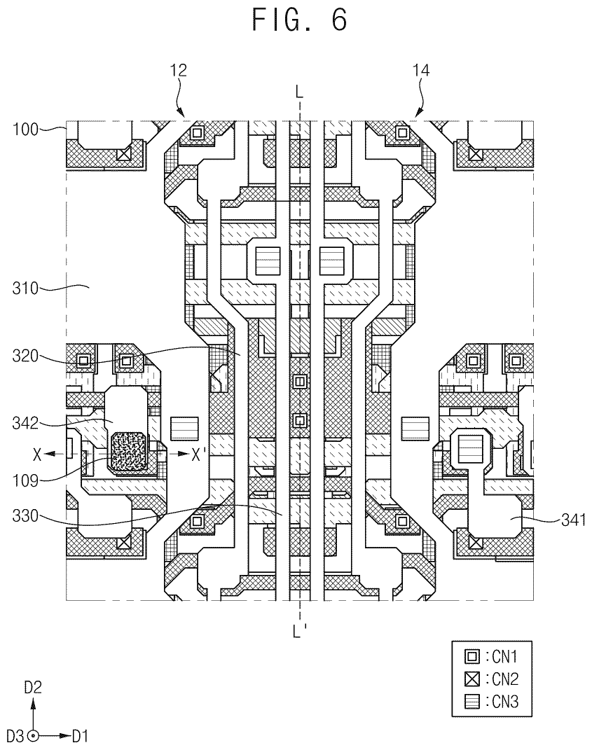

FIG. 1 is a schematic plan view illustrating a display device according to embodiments. FIGS. 2, 3, 5, and 6 are schematic cross-sectional views illustrating the levels of the layers in the display device according to embodiments. FIG. 3 is a schematic cross-sectional view taken along X-X′ line in FIG. 6.

Referring to FIG. 1, the display device 1 may include a display area DA where an image is displayed and a peripheral area PA outside the display area DA. The display device 1 may provide an image through pixels 10 (see FIG. 2). The peripheral area PA where an image is not provided may entirely or partially surround the display area DA. For example, each pixel may include a first sub-pixel 12 and a second sub-pixel 14.

Referring to FIGS. 1, 2, 3, 5, and 6, the display device 1 according to embodiment may include at least one wiring member, conductive member, at least one repair member, at least one light emitting member, etc. In embodiments, the at least one wiring member, the conductive member and the at least one repair member may be disposed in a pixel 10 of the display device 1.

The at least one wiring member may include a first wiring member and a second wiring member, the at least one repair member may include a first repair member 108 and a second repair member 109, and the at least one light emitting member may include a first light emitting member and a second light emitting member. For example, the first repair member 108 may be disposed between the first wiring member and the conductive member, and the second repair member may be disposed between the second wiring member and the second light emitting member.

For example, a plurality of transistors may be disposed in the pixel 10. For example, first to eighth transistors T1, T2, T3, T4, T5, T6, T7 and T8 may be disposed in the pixel 10. For example, the conductive member, the first wiring member and the second wiring member may be electrically connected to the plurality of transistors, respectively.

The pixel 10 may include the first sub-pixel 12 and the second sub-pixel 14 adjacent to each other in a first direction D1 or a second direction D2 substantially parallel to an upper surface of the substrate 100. Hereinafter, directions, which are substantially parallel to the upper surface of the substrate 100 and cross each other, may be defined as the first direction D1 and the second direction D2. For example, a direction substantially perpendicular to the upper surface of the substrate 100 may be defined as a third direction D3. For example, the first direction D1 may be substantially perpendicular to the second direction D2.

As illustrated in FIGS. 2, 3, 5, and 6, the first sub-pixel 12 and the second sub-pixel 14 may have structures that are symmetrical to each other centering a reference line L-L′. However, embodiments are not limited to these structures. In some embodiments, the first sub-pixel 12 and the second sub-pixel 14 may have a substantially same structure based on the reference line L-L′.

In embodiments, the first sub-pixel 12 may include a first light emitting layer capable of emitting a red (R) light, and the second sub-pixel 14 may include a second light emitting layer capable of emitting a green (G) light, however, embodiments are not limited thereto. In some embodiments, the first sub-pixel 12 and/or the second sub-pixel 14 may include alternatively or additionally a third light emitting layer capable of emitting a green (B) light.

The substrate 100 may include, for example, quartz substrate, synthetic quartz substrate, calcium fluoride substrate, F-doped quartz substrate, soda lime glass substrate, or non-alkali glass substrate, however, embodiments are not limited thereto. In some embodiments, the substrate 100 may have a single-layered structure including an organic layer, or a multi-layered structure including an organic layer and an inorganic layer. In embodiments, the substrate 100 may have a structure including a first base layer/a barrier layer/a second base layer. For example, each of the first base layer and the second base layer may include polymer resin. The barrier layer may have a single-layered structure or a multi-layered structure including an inorganic material such as silicon nitride (SiNₓ) or silicon oxynitride (SiOₓ).

For example, a buffer layer and a plurality of insulation layers (for example, gate insulation layers, insulating interlayers, protection layers, etc.) may be disposed on the substrate 100. The buffer layer may include an inorganic material such as silicon oxide (SiOx), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), or titanium oxide (TiOₓ). Alternatively, the buffer layer may include an organic material such as polyimide, polyamide, acrylic resin, benzocyclobutene resin, or phenol resin. Each of the insulation layers may include, for example, silicon oxide, silicon nitride, silicon oxynitride, polyimide, polyamide, etc.

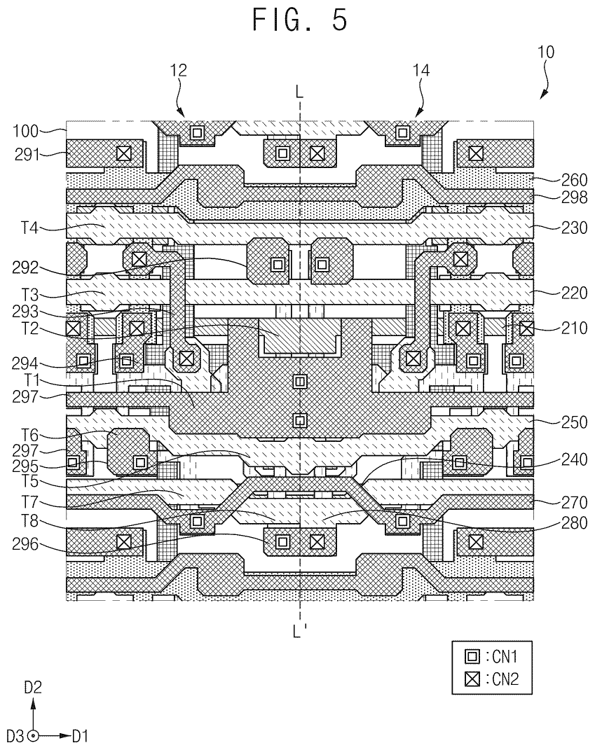

In the embodiments illustrated in FIG. 1 and FIG. 5, the first transistor T1, the second transistor T2, the third transistor T3, the fourth transistor T4, the fifth transistor T5, the sixth transistor T6, the seventh transistor T7 and the eight transistor T8 may be arranged in the pixel 10 of the display device 1, however, embodiments are not limited thereto. For example, the numbers of the transistors arranged the pixel 10 may vary in accordance with the configuration and/or function of the display device 1.

In embodiments, at least one of the first transistor T1, the second transistor T2, the fifth transistor T5, the sixth transistor T6, the seventh transistor T7 and the eighth transistor T8 may include a semiconductor material containing silicon. For example, the semiconductor material may include amorphous silicon, polysilicon, or combinations thereof. For example, in case that the first transistor T1 may affect the brightness of the display device 1, the first transistor T1 may include the semiconductor material containing polysilicon of relatively high reliability. Therefore, the display device 1 including the first transistor T1 may have the relatively high brightness.

At least one of the third transistor T3 and the fourth transistor T4 may include an oxide semiconductor material. In embodiments, the third transistor T3 and the fourth transistor T4 may be electrically connected to a gate of the first transistor T1. For example, at least one of the third transistor T3 and the fourth transistor T4 may include an oxide semiconductor material having relatively high carrier mobility and relatively low leakage current. Therefore, the leakage current flowing to the gate of the first transistor T1 may be prevented, and also the power consumption of the display device 1 may be reduced.

As illustrated in FIG. 2, the first wiring member may include first to fourth scan lines 210, 220, 230 and 240, an emission control line 250, a first initialization voltage line 260, a second initialization voltage line 270, a vias voltage line 280, etc.

A first scan line 210 of the first wiring member may be electrically connected to a second gate of the second transistor T2. For example, the first scan line 210 may be electrically connected to the second gate of the second transistor T2 at a point where the first scan line 210 extending in the first direction D1 on the substrate 100 crosses the second transistor T2 extending in the second direction D2 on the substrate 100. The second transistor T2 may be turned on in response to a first scan signal applied through the first scan line 210. For example, the first scan signal may be a data input signal.

At least a portion of a second scan line 220 of the first wiring member may be electrically connected to a gate of the third transistor T3. For example, the second scan line 220 may be electrically connected to the gate of the third transistor T3 at a point where the second scan line 220 extending in the first direction D1 on the substrate 10 crosses the third transistor T3 extending in the second direction D2 on the substrate 100. The third transistor T3 may be turned on in response to a second scan signal transmitted through the second scan line 220. The second scan signal may be, for example, a threshold voltage compensation signal.

At least a portion of a third scan line 230 of the first wiring member may be electrically connected to a gate of the fourth transistor T4. For example, the third scan line 230 may be electrically connected to the gate of the fourth transistor T4 at a point where the third scan line 230 extending in the first direction D1 on the substrate 10 crosses the fourth transistor T4 extending in the second direction D2 on the substrate 100. The fourth transistor T4 may be turned on in response to a third scan signal applied through the third scan line 230. For example, the third scan signal may be a first initialization signal.

At least a portion of a fourth scan line 240 of the first wiring member may be electrically connected to a gate of the seventh transistor T7 and a gate of the eighth transistor T8. For example, the fourth scan line 240 may be electrically connected to the gate of the seventh transistor T7 and the gate of the eighth transistor T8 at points where the fourth scan line 240 extending in the first direction D1 on the substrate 100 crosses the seventh transistor T7 and the eighth transistor T8 extending in the second direction D2 on the substrate 100. Each of the seventh transistor T7 and the eighth transistor T8 may be turned on in response to a fourth scan signal transmitted through the fourth scan line 240. The fourth scan signal may be, for example, a bias signal.

Each of the first scan line 210 and the fourth scan line 240 of the first wiring member and the gate of the first transistor T1 may include metal such as copper (Cu), molybdenum (Mo), aluminum (Al) or titanium (Ti), or alloys of these metals. For example, each of the first scan line 210, the fourth scan line 240 and the gate or the first transistor T1 may include may be formed by forming a first conductive layer on the substrate 100 and by patterning the first conductive layer. For example, the first conductive layer may be composed of a single layer or multi-layers. In embodiments, the gate of the first transistor T1 may be a lower electrode of a capacitor disposed in the pixel 10.

An emission control line 250 of the first wiring member may be electrically connected to the gate of the fifth transistor T5 and the gate of the sixth transistor T6. For example, the emission control line 250 may be electrically connected to the gate of the fifth transistor T5 and the gate of the sixth transistor T6 at points where the emission control line 250 extending on the substrate in the first direction D1 crosses the fifth transistor T5 and the sixth transistor T6 extending on the substrate 100 in the second direction D2. Each of the fifth transistor T5 and the sixth transistor T6 may be turned on in response to an emission control signal applied to the emission control line 250.

In embodiments, a first initialization voltage may initialize the gate of the first transistor T1 and may be applied to a first terminal of the fourth transistor T4 through a first initialization voltage line 260 of the first wiring member. A second initialization voltage may be applied to a first terminal of the seventh transistor T7 through a second initialization voltage line 270 of the first wiring member. For example, a vias voltage may be applied to a first terminal of the eighth transistor T8 through a vias voltage line 280 of the first wiring member.

Each of the second scan line 220, the third scan line 230, the emission control line 250 and the vias voltage line 280 may include metal such as copper, molybdenum, aluminum or titanium, or alloys of these metals. In embodiments, each of the second scan line 220, the third scan line 230, the emission control line 250 and the vias voltage line 280 may be formed by patterning a second conductive layer having a single-layered structure or a multi-layered structure after forming the second conductive layer on the substrate 100.

The conductive member may include first to sixth connection patterns 291, 292, 293, 294, 295 and 296, a driving voltage connection line 297, and a first auxiliary data line 298. Each of the conductive member and the second initialization voltage line 270 of the first wiring member may include metal such as copper, molybdenum, aluminum or titanium, or alloys of these metals. In embodiments, each of the conductive member and the second initialization voltage line 270 may be formed by patterning a third conductive layer after forming the third conductive layer on the substrate 100. For example, the third conductive layer may have a single-layered structure or a multi-layered structure.

As illustrated in FIGS. 2 and 5, each of the second initialization voltage line 270, the driving voltage connection line 297 and the first auxiliary data line 298 may extend on the substrate 100 along the first direction D1.

The second initialization voltage line 270 of the first wiring member may be electrically connected to the first terminal of the seventh transistor T7 via a first contact CN1. Therefore, the second initialization voltage may be applied to the seventh transistor T7 through the second initialization voltage line 270. For example, the driving voltage connection line 297 may be electrically connected to the first terminal of the fifth transistor T5 and an upper electrode of the capacitor disposed in the pixel 10. Thus, a driving voltage may be applied to the first terminal of the fifth transistor T5 and an upper electrode of the capacitor through the driving voltage connection line 297. In the drawings, contacts of substantially same functional and structural features may be represented as first contacts CN1, second contacts CN2 and third contacts CN1.

In embodiments, each of the first to the sixth connection patterns 291, 292, 293, 294, 295 and 296 of the conductive member may have an island shape. The first connection pattern 291 may partially overlap the first terminal of the fourth transistor T4 and may partially overlap an extension of the first initialization voltage line 260 extending along the second direction D2. For example, the first connection pattern 291 may be electrically connected to the first terminal of the fourth transistor T4 via the second contact CN2, and may partially overlap the extension of the first initialization voltage line 260 extending the second direction D2 via the second contact CN2. Therefore, the first initialization voltage may be applied to the first terminal of the fourth transistor T4 through the first initialization voltage line 260 and the first connection pattern 291.

The second connection pattern 292 may partially overlap the first terminal of the second transistor T2, and may partially overlap at least a portion of the first wiring member. For example, the second connection pattern 292 may partially overlap at least a portion of the second scan line 220 and/or the third scan line 230 of the first wiring member. The second connection pattern 292 may be electrically connected to the first terminal of the second transistor T2 via the first contact CN1, and may be electrically connected to the data voltage line 330 via the third contact CN3 (see FIG. 5).

The third connection pattern 293 of the conductive member may be electrically connected to a second terminal of the third transistor T3 and a second terminal of the fourth transistor T4 via the second contacts CN2 disposed at opposite end portions of the third connection pattern 293. For example, the third connection pattern 293 may be electrically connected to the lower electrode of the capacitor such that each of the second terminal of the third transistor T3 and the second terminal of the fourth transistor T4 may be electrically connected to the lower electrode of the capacitor through the third connection pattern 293.

The fourth connection pattern 294 of the conductive member may be electrically connected to the first terminal of the third transistor T3 via the second contact CN2 and may be electrically connected to the first terminal of the sixth transistor T6 via first contact CN1. Thus, the first terminal of the third transistor T3 may be electrically connected to the first terminal of the sixth transistor T6 through the fourth connection pattern 294.

The fifth connection pattern 295 of the conductive member may be electrically connected to a second terminal of the seventh transistor T7 and a second terminal of the sixth transistor T6 via the first contacts CN1. Therefore, the second terminal of the seventh transistor T7 may be electrically connected to the second terminal of the sixth transistor T6 through the fifth connection pattern 295. For example, the fifth connection pattern 295 of the conductive member may partially overlap the second terminal of the seventh transistor T7 and the second terminal of the sixth transistor T6, and at least a portion of the fifth connection pattern 295 may partially overlap at least a portion of the first wiring member. For example, the fifth connection pattern 295 of the conductive member may partially overlap the emission control line 250 of the first wiring member.

The sixth connection pattern 296 of the conductive member may be electrically connected to the vias voltage line 280 via the second contact CN2, and may be electrically connected to the first terminal of the eighth transistor T8 via the first contact CN1. Thus, the vias voltage may be applied to the first terminal of the eighth transistor T8 through the sixth connection pattern 296.

As illustrated in FIG. 3, the second wiring member may include a driving voltage line 310, a second auxiliary data line 320 and a data voltage line 330. In some embodiments, the second wiring member may additionally include at least one conductive pattern. For example, the at least one conductive pattern may include a seventh connection pattern 341 and an eighth connection pattern 342. The second wiring member may partially overlap the conductive member. For example, the data voltage line 330 of the second wiring member may partially overlap the second connection pattern 292 of the conductive member. For example, the eighth connection pattern 340 of the second wiring member may partially overlap the fifth connection pattern 295 of the conductive member.

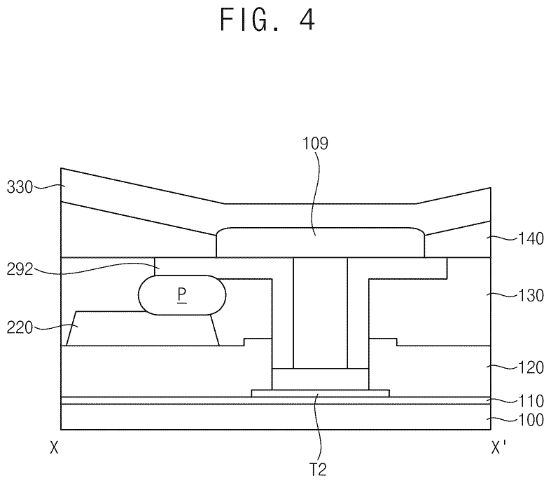

FIG. 4 is a schematic cross-sectional view illustrating a repair member of the display device 1 in accordance with embodiments.

As illustrated in FIG. 4, the second transistor T2 may be disposed on a buffer layer 110 formed on the substrate 100, a first insulating interlayer 120 may be disposed on the buffer layer 110 to cover the second transistor T2, and the second scan line 220 of the first wiring member may be disposed on the first insulating interlayer 120. For example, a second insulating interlayer 130 may be disposed on the first insulating interlayer 120 to cover the second scan line 220, the second connection pattern 292 of the conductive member may be disposed in the second insulating interlayer 130, and a protection layer 140 may be disposed on the second connection pattern 292 and the second insulating interlayer 130.

In the processes for manufacturing the display device 1, failures or defects may occur between the conductive member and the first wiring member due to impurities and/or process errors. For example, failure such as short circuit P may occur between the second connection pattern 292 of the conductive member and the second scan line 220 of the first wiring member. In case that the short circuit P occurs between the conductive member and the first wiring member, failure of bright spot (for example, life defect) may occur in the pixel 10 having the short circuit P as well as other pixels arranged in a same row and in a same column. In case that the short circuit P is detected between the second connection pattern 292 of the conductive member and the second scan line 220 of the first wiring member, the components of the display device 1 overlying (or connected to) the second connection pattern 292 may be damaged in a repair process using a laser. For example, the laser may cause damage to the components of the display device 1 overlying (or connected to) the second connection pattern 292 in the repair process.

According to embodiments, the display device 1 may include a first repair member 108 which blocks the electrical connection between the second connection pattern 292 and the data voltage line 330 in case that the short circuit P occurs between the second connection pattern 292 of the conductive member and the second scan line 220 of first wiring member. Therefore, the failure such as the line defect may be prevented in the display device 1 without performing the repair process using the laser.

In embodiments, the first repair member 108 may be disposed on the second connection pattern 292 of the conductive member. For example, the first repair member 108 may be disposed on the second connection pattern 292 such that the first repair member 108 may at least partially overlap the third contact CN3 on the second connection pattern 292. The first repair member 108 may block the electrical connection between the second connection pattern 292 and the data voltage line 320. Accordingly, in case that the failure such as the short circuit P may occur between the second connection pattern 292 and the second scan line 220 due to the impurities and/or the process errors, the first repair member 108 may block the electrical connection between the second connection pattern 292 and the data voltage line 320 to prevent the failure such as the line defect in the display device 1.

In embodiments, the first repair member 108 may include an organic insulation material. Examples of the organic insulation material included in the first repair member 108 may include polyimide, polyamide, acrylic resin, benzocyclobutene resin, or phenol resin, however, embodiments are not limited thereto. In some embodiments, the first repair member 108 may be an inorganic insulation material. Examples of the organic insulation material included in the first repair member 108 may include silicon oxide (SiOₓ), silicon nitride (SiNx), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), or titanium oxide (TiOₓ), however, embodiments are not limited thereto.

For example, the first repair member 108 may be formed by an electro hydrodynamics (EHD) inkjet process using the organic insulation material or the organic insulation material, however, embodiments are not limited thereto. In some embodiments, the first repair member 108 may be formed by a sputtering process, a plasma enhanced chemical vapor deposition (PECVD) process, an metal organic chemical vapor deposition (MOCVD) process, an atomic layer deposition (ALD) process, a pulse laser deposition (PLD) process, a sol-gel process, a spin coating process, a spray coating process, a dip coating process, or an inkjet coating process.

As illustrated in FIG. 3, the driving voltage line 310 of the second wiring member may extend on the substrate 100 along the second direction D2, and may be electrically connected to the driving voltage connection line 297 via the third contact CN3. Therefore, the driving voltage may be applied to the first terminal of the fifth transistor T5 and the upper electrode of the capacitor through the driving voltage connection line 297 and the driving voltage line 310. For example, the driving voltage may be a voltage of relatively high level, however, embodiments are not limited thereto. In some embodiments, the driving voltage may be a voltage of relatively low level.

The second auxiliary data line 320 of the second wiring member may extend on the substrate 100 in the second direction D2, and may partially overlap the first auxiliary data line 298. Further, the data voltage line 330 of the second wiring member may extend on the substrate 100 along the second direction D2, and may be electrically connected to the second connection pattern 292 of the conductive member via the third contact CN3. Thus, the data voltage may be applied to the second terminal of the second transistor T2 through the second connection pattern 292 and the data voltage line 330.

Each of the seventh connection pattern 341 and the eighth connection pattern 342 may partially overlap the fifth connection pattern 295. The seventh connection pattern 341 and the eighth connection pattern 342 may be electrically connected to the fifth connection pattern 295 via the third contacts CN3, respectively. Thus, the seventh connection pattern 341 and the eighth connection pattern 342 may be electrically connected to the second terminal of the seventh transistor T7 and the second terminal of the sixth transistor T6, respectively.

The seventh connection pattern 341 may be electrically connected to a first light emitting member disposed on the second wiring member through a fourth contact. The eighth connection pattern 342 may be electrically connected to a second light emitting member disposed on the second wiring member through a fourth contact. The first light emitting member and the second light emitting member may be disposed in the first sub-pixel 12 and the second sub-pixel 14, respectively. Each of the first light emitting member and the second light emitting member may include a first electrode, an organic light emitting layer and a second electrode. In embodiments, the organic light emitting layer of the first light emitting member may emit a red (R) light, and the organic light emitting layer of the second light emitting member may emit a green (G) light, however, embodiments are not limited thereto.

In the processes for manufacturing the display device 1, due to the impurities and/or the process errors, failure such as short circuit may occur between the first wiring member and the conductive member. For example, the short circuit may occur between the eighth connection pattern 342 of the second wiring member and the emission control line 250 of the first wiring member. In case that the short circuit is detected between the fifth connection pattern 295 and the emission control line 250, a second repair member 109 may block the electrical connection between the eighth connection pattern 342 of the second wiring member and the second light emitting member such that failure such as line defect may be prevented in the display device 1 without performing a repair process using a laser.

The second repair member 109 may be disposed on the eighth connection pattern 342 of the second wiring member, and the second repair member 109 may substantially or partially overlap the fourth contact on the eighth connection pattern 342 of the second wiring member, so that the second repair member 109 may block the electrical connection between the eighth connection pattern 342 and the second light emitting member. Therefore, in case that the failure such as the short circuit occurs between the eighth connection pattern 342 and the second light emitting member due to the impurities and/or the process errors, the second repair member 109 may block the electrical connection between the second wiring member and the second light emitting member to prevent the failure such as the line defect in the display device 1.

In embodiments, the second repair member 109 may include an organic insulation material or an inorganic insulation material. Examples of the organic material included in the second repair member 109 may include polyimide, polyamide, acrylic resin, benzocyclobutene resin, phenol resin or combinations thereof, however, embodiments are not limited thereto. Further, examples of the inorganic material included in the second repair member 109 may include silicon oxide, silicon nitride, silicon oxynitride, silicon oxycarbide, silicon carbonitride, aluminum oxide, aluminum nitride, tantalum oxide, hafnium oxide, zirconium oxide, titanium oxide, or combinations thereof, however, embodiments are not limited thereto.

For example, the second repair member 109 may be formed by an electro hydrodynamics inkjet process using the organic insulation material or the inorganic insulation material, however, embodiments are not limited thereto. In some embodiments, the second repair member 109 may be formed by a sputtering process, a plasma enhanced chemical vapor deposition process, an metal organic chemical vapor deposition process, an atomic layer deposition process, a pulse laser deposition process, a sol-gel process, a spin coating process, a spray coating process, a dip coating process, or an inkjet coating process.

The display devices 1 according to embodiments may be employed (or implemented) in various electronic apparatuses as described below. The electronic apparatuses may include the display devices 1 having the above-described configurations and may additionally or selectively include modules or devices having optional functions.

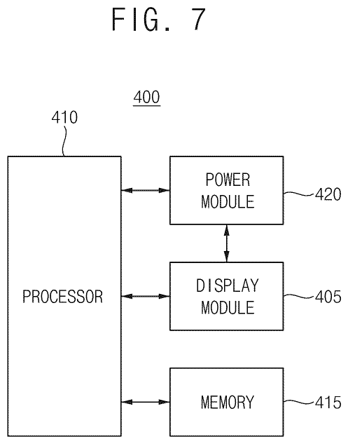

FIG. 7 is a block diagram illustrating an electronic apparatus according to embodiments.

Referring to FIG. 7, an electronic apparatus 400 may include a display module 405, a processor 410, a memory 415, a power module 420, etc.

The processor 410 may include one or more of a central processing unit (CPU), an application processor (AP), a graphic processing unit (GPU), a communication processor (CP), an image signal processor (ISP) and a controller.

The memory 415 may store an information for operating the processor 410 or the display module 405. In case that the processor 410 executes an application or a program stored in the memory 415, the processor 410 may provide an image data signal and/or an input control signal to the display module 405. The display module 405 may process the provided image data signal and/or the provided input control signal, and then may output image information on a display screen of the electronic apparatus 400.

The power module 420 may include a power supply module such as a power adaptor or a battery device, and a power conversion module which converts the power supplied from the power supply module and generate the power needed to operate the electronic apparatus 400.

In embodiments, one or more of the components in the electronic apparatus 400 may be included in the display devices 1 according to an embodiments. For example, some of individual modules in the modules entirely performing one function may be included in the display device 1 whereas others of the individual modules may be provided separately from the display device 1. For example, the display module 405 may be included in the display device 1 whereas the processor 410, the memory 415 and the power module 420 may be provided as other types besides the display device 1 in the electronic apparatus 400.

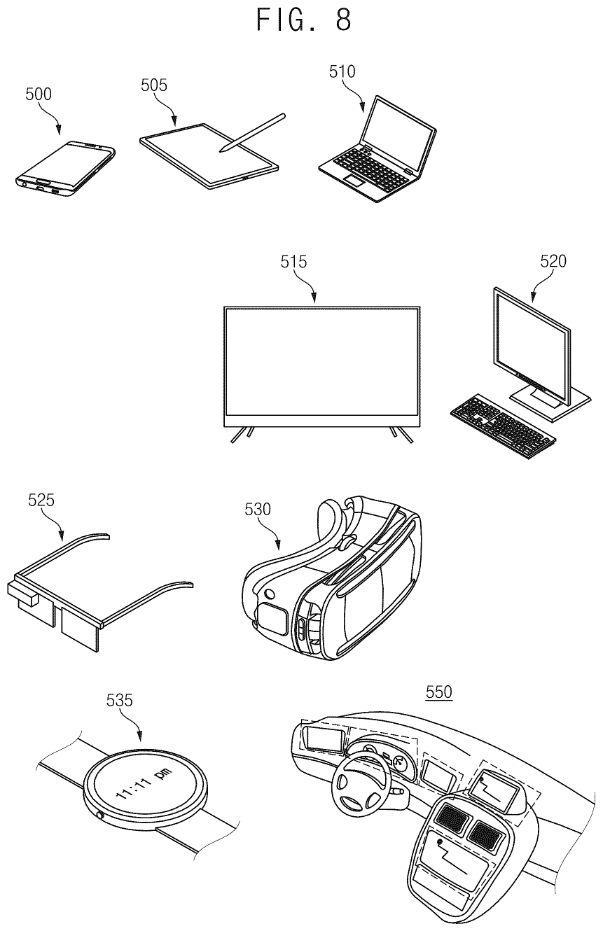

FIG. 8 illustrates schematic perspective views various electronic apparatuses according to embodiments.

Referring to FIG. 8, various electronic apparatuses having the display devices 1 according to embodiments may include an electronic apparatus for displaying images such as a smart phone 500, a tablet personal computer 505, a laptop 510, a television 515, a monitor for desktop 520, etc. For example, the electronic apparatuses may include a wearable electronic apparatus having a display module such as smart glasses 525, a head-mounted display 530, a smart watch 535, etc. Furthermore, the electronic apparatuses may include a vehicle-mounted electronic apparatus having a display module 550, for example, display units for vehicle, a center fascia, a center information display (CID) on a dashboard, a room mirror display, etc.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a conductive member disposed on a substrate;
at least one wiring member disposed on the conductive member, the at least one wiring member being electrically connected to the conductive member;
at least one light emitting member disposed on the at least one wiring member; and
at least one repair member disposed between the conductive member and the at least one wiring member, the at least one repair member that prevents a short circuit among the conductive member, the at least one wiring member, and the at least one light emitting member.

2. The display device of claim 1, wherein
the at least one wiring member comprises a first wiring member and a second wiring member,
the at least one repair member comprises a first repair member and a second repair member,
the first repair member is disposed between the conductive member and the first wiring member and prevents a short circuit between the conductive member and the first wiring member, and
the second repair member is disposed between the second wiring member and the at least one light emitting member and prevents a short circuit between the second wiring member and the at least one light emitting member.

3. The display device of claim 2, wherein
the first wiring member comprises at least one scan line,
the conductive member comprises at least one connection pattern, and
the first repair member is disposed between the at least one scan line of the conductive member and the at least one connection pattern of the conductive member and prevents a short circuit between the at least one scan line of the conductive member and the at least one connection pattern of the conductive member.

4. The display device of claim 3, wherein the first repair member is disposed on the at least one connection pattern of the conductive member.

5. The display device of claim 2, wherein
the second wiring member comprises at least one connection pattern, and
the second repair member prevents a short circuit between the at least one connection pattern of the second wiring member and the at least one light emitting member.

6. The display device of claim 5, wherein the second wiring member partially overlaps the conductive member.

7. The display device of claim 5, wherein the second repair member is disposed on the at least one connection pattern of the second wiring member.

8. The display device of claim 2, wherein each of the first repair member and the second repair member comprises an organic insulation material.

9. The display device of claim 8, wherein the organic insulation material includes polyimide, polyamide, acrylic resin, benzocyclobutene resin, phenol resin, or combinations thereof.

10. The display device of claim 2, wherein each of the first repair member and the second repair member comprises an inorganic insulation material.

11. The display device of claim 10, wherein the inorganic insulation material includes silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), or combinations thereof.

12. A display device comprising:
a conductive member disposed on a substrate;
a first wiring member and a second wiring member disposed on the conductive member, the first wiring member and the second wiring member being electrically connected to the conductive member;
at least one light emitting member disposed on the first wiring member and the second wiring member;
a first repair member disposed between a portion of the first wiring member and a portion of the conductive member, the first repair member that prevents a short circuit between the portion of the first wiring member and the portion of the conductive member; and
a second repair member disposed between a portion of the second wiring member and the at least one light emitting member, the second repair member that prevents a short circuit between the portion of the second wiring member and the at least one light emitting member.

13. The display device of claim 12, further comprising:
a plurality of transistors disposed on the substrate, wherein
the plurality of transistors are electrically connected to the conductive member, the first wiring member, and the second wiring member, respectively.

14. The display device of claim 12, wherein
the first wiring member comprises a scan line,
the conductive member comprises a connection pattern, and
the first repair member is disposed between the scan line of the first wiring member and the connection pattern of the conductive member and prevents a short circuit between the scan line of the first wiring member and the connection pattern of the conductive member.

15. The display device of claim 12, wherein
the second wiring member comprises a connection pattern, and
the second repair member is disposed between the connection of the second wiring member and the at least one light emitting member and prevents a short circuit between the connection pattern of the second wiring member and the at least one light emitting member.

16. The display device of claim 12, wherein each of the first repair member and the second repair member comprises an organic insulation material.

17. The display device of claim 12, wherein each of the first repair member and the second repair member comprises an inorganic insulation material.

18. An electronic apparatus comprising:
a processor providing an image data signal and an input control signal;
a memory storing an information for operating the processor; and
a display device processing the image data signal and the input control signal, and outputting an image information disposed on a display screen,
wherein the display device comprises:
a plurality of transistors disposed on a substrate;
a conductive member electrically connected to the plurality of transistors;
a first wiring member and a second wiring member electrically connected to the plurality of transistors and the conductive member;
a first light emitting member and a second light emitting member disposed on the first wiring member and the second wiring member;
a first repair member disposed between a portion of the first wiring member and a portion of the conductive member, the first repair member that prevents a short circuit between the portion of the first wiring member and the portion of the conductive member; and
a second repair member disposed between a portion of the second wiring member and the second light emitting member, the second repair member that prevents a short circuit between the portion of the second wiring member and the second light emitting member.

19. The electronic apparatus of claim 18, wherein
the first repair member is disposed on the portion of the first wiring member, and
the second repair member is disposed on the portion of the second wiring member.

20. The electronic apparatus of claim 19, wherein each of the first repair member and the second repair member comprises at least one of an organic insulation material and an inorganic insulation material.
